(19) United States
(12) Patent Application Publication
(10) Pub. No.: US 2024/0086155 A1
(43) Pub. Date: Mar. 14, 2024

(54) COMPUTATION METHOD AND COMPUTATION APPARATUS WITH INPUT SWAPPING

(71) Applicant: Taiwan Semiconductor Manufacturing Company, Ltd., Hsinchu (TW)

(72) Inventors: Win-San Khwa, Taipei City (TW); Yi-Lun Lu, New Taipei City (TW); Jui-Jen Wu, Hsinchu (TW); Meng-Fan Chang, Taichung City (TW)

(73) Assignee: Taiwan Semiconductor Manufacturing Company, Ltd., Hsinchu (TW)

(21) Appl. No.: 18/150,810

(22) Filed: Jan. 6, 2023

Related U.S. Application Data
(60) Provisional application No. 63/404,545, filed on Sep. 8, 2022.
(60) Provisional application No. 63/434,924, filed on Dec. 22, 2022.

(51) Int. Cl. G06F 7/76; G06F 7/501; H03K 19/21

(52) U.S. Cl. CPC G06F 7/768; G06F 7/501; H03K 19/21

(57) ABSTRACT

A computation apparatus and a computation method with input swapping are provided. The computation apparatus includes a non-zero detection circuit, a swapper policy circuit, a swapper matrix circuit, and an adder tree. The non-zero detection circuit is configured to receive input vectors, inspect non-zero operands in the input vectors and generate a non-zero indicative signal indicating the non-zero operands. The swapper policy circuit is configured to receive and interpret the non-zero indicative signal, and generate multiplexer (MUX) selection signals for swapping the non-zero operands according to a set of swapping policies. The swapper matrix circuit is configured to receive the input vectors and the MUX selection signal, and perform swapping on operands in the input vectors according to the MUX selection signal. The adder tree is configured to receive the input vectors with the swapped operands and perform additions on the input vectors to output a computation result.

### CROSS-REFERENCE TO RELATED APPLICATION

This application claims the priority benefit of U.S. provisional application Ser. No. 63/404,545, filed on Sep. 8, 2022 and U.S. provisional application Ser. No. 63/434,924, filed on Dec. 22, 2022. The entirety of each of the above-mentioned patent applications is hereby incorporated by reference herein and made a part of specification.

### BACKGROUND

Data input to neural network for computation typically has a high-level of sparsity (i.e. input is a zero vector). In general, a ResNet-20 network trained using CIFAR-100 dataset may have around 40% to 50% input sparsity.

In conventional applications, adder trees have no incentive to deal with inputs because there is no sparsity involved. As such, the number of active adders used in computations of neural network in an adder tree remains high and the computation power consumed by the adder tree cannot be reduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a computation apparatus in accordance with some embodiments of the present disclosure.

FIG. 1B illustrates comparison between the input vectors before input swapping and the input vectors after input swapping.

FIG. 2 is a flowchart of a computation method with input swapping in accordance with some embodiments of the present disclosure.

FIG. 3A illustrates the swapper policy in accordance with some embodiments of the present disclosure.

FIG. 3B illustrates the swapper matrix in accordance with some embodiments of the present disclosure.

FIG. 4 is a flowchart of a computation method with input swapping in accordance with some embodiments of the present disclosure.

FIG. 5 is a circuit diagram of a computation apparatus in accordance with some embodiments of the present disclosure.

FIG. 6 is a circuit diagram of a non-zero detection circuit in accordance with some embodiments of the present disclosure.

FIGS. 7A to 7E are circuit diagrams of a swapper policy circuit in accordance with some embodiments of the present disclosure.

FIGS. 8A to 8K are circuit diagrams of a swapper matrix circuit in accordance with some embodiments of the present disclosure.

FIGS. 9A to 9D are circuit diagrams of adders in accordance with some embodiments of the present disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth” and the like, may be used herein for ease of description to describe similar or different element(s) or feature(s) as illustrated in the figures, and may be used interchangeably depending on the order of the presence or the contexts of the description.

Due to input sparsity in computation of neural network, the computation power of an adder tree could be reduced significantly by swapping input vectors to minimize the number of active adders. Accordingly, the present application provides a computation apparatus and computation method with input swapping.

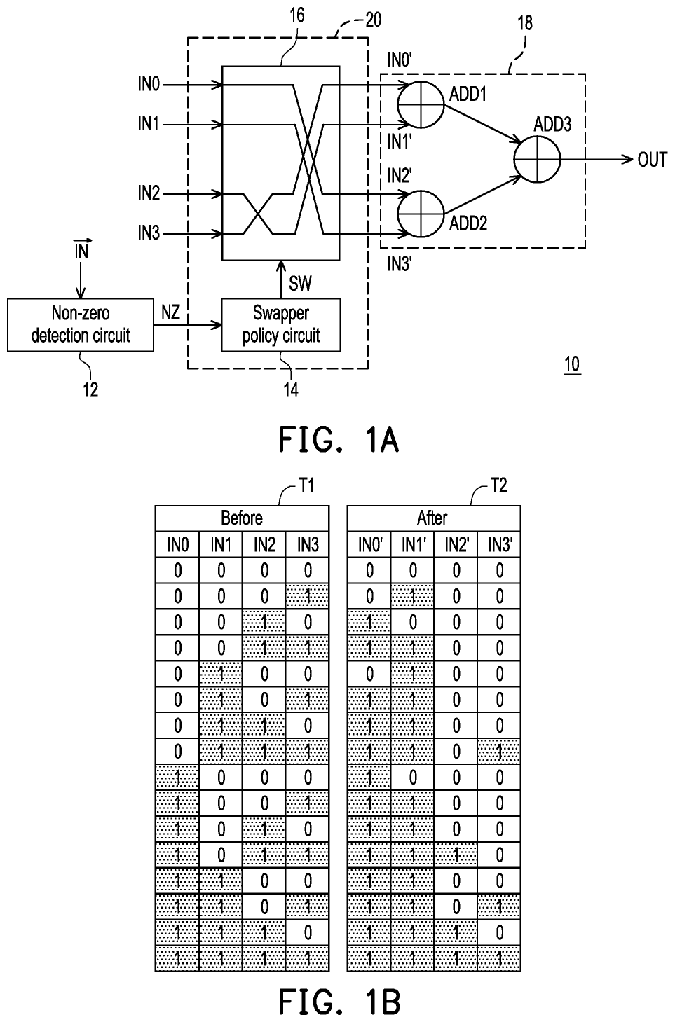

FIG. 1A is a schematic diagram of a computation apparatus in accordance with some embodiments of the present disclosure, and FIG. 1B illustrates comparison between the input vectors before input swapping and the input vectors after input swapping. Referring to FIG. 1A, a computation apparatus 100 of the present embodiment may be applied to perform additions in multiply-accumulate (MAC) operations in a neural network, and includes a non-zero detection circuit 12, a swapper policy circuit 14, a swapper matrix circuit 16, and an adder tree 18.

The non-zero detection circuit 12 is configured to receive input vectors \vec{IN}, inspect non-zero operands in the input vectors \vec{IN} and generate a non-zero indicative signal NZ indicating the non-zero operands. In some embodiments, each of the input vectors \vec{IN} includes operands IN0 to IN3 obtained by inputs multiplied by weights, and the non-zero detection circuit 12 detects if each operand in the input vectors \vec{IN} is zero or non-zero, and generates the non-zero indicative signal NZ indicating the non-zero operands.

The swapper policy circuit 14 is connected to the non-zero detection circuit 12 and configured to receive the non-zero indicative signal NZ generated by the non-zero detection circuit 12, interpret the non-zero indicative signal NZ, and generate multiplexer (MUX) selection signals SW for swapping the non-zero operands according to a set of swapping policies, which will be described later.

The swapper matrix circuit 16 is connected to the swapper policy circuit 14 and configured to receive the input vectors \vec{IN} with operands IN0 to IN3 and the MUX selection signals SW, and perform swapping on operands in the input vectors \vec{IN} according to the MUX selection signals SW. That is, the swapper matrix circuit 16 may re-arrange the operands IN0 to IN3 in the input vectors \vec{IN} to consolidate the non-zero operands on one side of the adder tree 18.

The adder tree 18 is connected to the swapper matrix circuit 16 and configured to receive the swapped operands IN0′ to IN3′ output by the swapper matrix circuit 16 and perform additions on the received operands IN0′ to IN3′ to output a computation result OUT. In the present embodiments, the adder tree 18 is a two-level adder tree including adders ADD1 to ADD3, in which the adder ADD1 receives the swapped operands IN0′ and IN1′ and generates an addition result, the adder ADD2 receives the swapped operands IN2′ and IN3′ and generate another addition result, and the adder ADD3 receives the addition results of the adders ADD1 and ADD2 and generates a computation result OUT.

Referring to FIG. 1B, table T1 lists binary operands IN0 to IN3 of decimal values 0 to 15 before input swapping, and table T2 lists swapped operands IN0′ to IN3′ obtained after performing input swapping on the binary operands IN0 to IN3 according to a set of swapping policies. Comparing table T1 with table T2, the non-zero operands in table T1 are consolidated toward the left as shown in table T2. As a result, a number of active adders used for performing additions on the operands with a value of 1 in the adder tree can be reduced, and the energy consumed by the adder tree can be reduced.

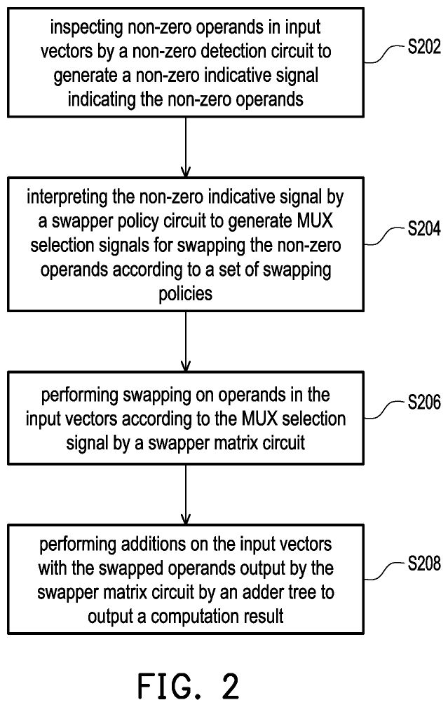

FIG. 2 is a flowchart of a computation method with input swapping in accordance with some embodiments of the present disclosure. Referring to FIG. 1 to FIG. 2, the computation method of the present embodiments is applied to the computation apparatus 10 in FIG. 1.

In step S202, the non-zero detection circuit 12 inspects non-zero operands in input vectors to generate a non-zero indicative signal NZ indicating the non-zero operands.

In step S204, the swapper policy circuit 14 interprets the non-zero indicative signal NZ to generate MUX selection signals SW for swapping the non-zero operands according to a set of swapping policies.

In step S206, the swapper matrix circuit 16 performs swapping on operands in the input vectors according to the MUX selection signal SW.

In step S208, the adder tree 18 performs additions on the input vectors with the swapped operands output by the swapper matrix circuit 16 to output a computation result OUT.

It is noted, in the present embodiment, a two-level adder tree is adopted to perform additions on the four operands IN0′ to IN3′ swapped from the input vector IN, but the present application is not limited thereto. In other embodiments, an adder tree with various levels of adders or various numbers of adders may be adopted in accordance with a number of operands to be added.

In some embodiments, the swapping policies applied by the swapper policy circuit 14 includes: in response to the operand in a former order of an input vector being inspected as zero, swapping the non-zero operand in a latter order of the input vector with the operand in the former order of the input vector; and in response to a first set of the operands to be swapped in a first stage both being non-zero operands, swapping the non-zero operand in a latter order in the first set with a zero operand in a latter order in a second set of the operands having two zero operands in a second stage before the first stage, and swapping the non-zero operand being swapped to the second set with the operand in a former order in the second set.

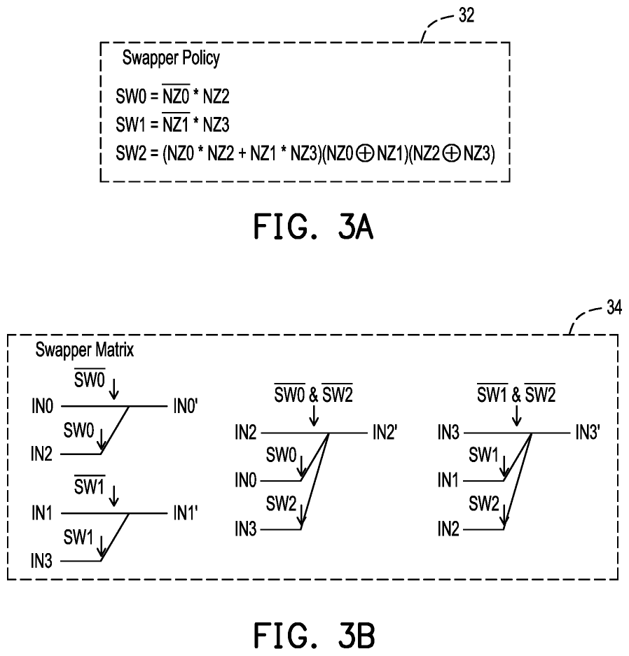

FIG. 3A illustrates the swapper policy in accordance with some embodiments of the present disclosure, and FIG. 3B illustrates the swapper matrix in accordance with some embodiments of the present disclosure. Referring to FIG. 3A, the present embodiment takes in the non-zero indicative signals NZ and generates the MUX selection signals SW according to the combinational logics in the swapper policy 32.

Referring to both FIG. 3A and FIG. 3B, the swapper matrix 34 is a two-stage transmission gate matrix that re-arranges input operands according to the MUX selection signals SW.

In a first stage, as illustrated in the logics of SW0 and SW1 in the swapper policy 32, the operand IN2 is swapped with the operand IN0 while the operand IN3 is swapped with the operand IN1, so as to consolidate the non-zero operands to the top.

In a second stage, as illustrated in the logic of SW2 in the swapper policy 32, when the operands IN0 and IN2 are both non-zeros or the operands IN1 and IN3 are both non-zeros, a swapping between the operands IN2 and IN3 may be performed. That is, the operand IN2 may be swapped with the operand IN3 according to the selection signal SW0 and then swapped with the operand IN1 to reach the top, and the operand IN3 may be swapped with the operand IN2 and then swapped with the operand IN0 to reach the top.

As shown in the swapper matrix 34, the input operands IN0 and IN2 are swapped according to the MUX selection signals SW0 and S̅W̅0̅. The input operands IN1 and IN3 are swapped according to the MUX selection signals SW1 and S̅W̅1̅. The input operands IN0, IN2 and IN3 are swapped according to the MUX selection signals SW0, SW2, S̅W̅0̅ and S̅W̅2̅. The input operands IN3, IN1 and IN2 are swapped according to the MUX selection signals SW1, SW2, S̅W̅1̅ and S̅W̅2̅.

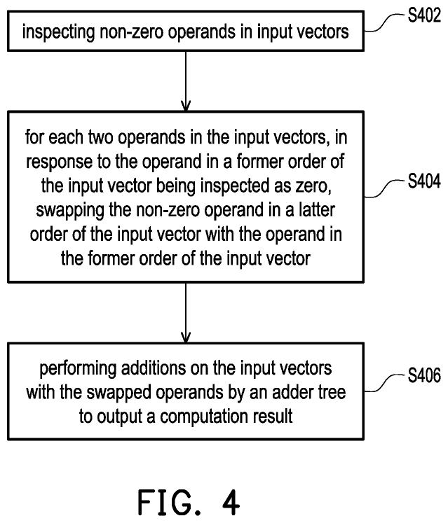

FIG. 4 is a flowchart of a computation method with input swapping in accordance with some embodiments of the present disclosure. Referring to FIG. 1 to FIG. 4, the computation method of the present embodiments is applied to the computation apparatus 10 in FIG. 1.

In step S402, the non-zero detection circuit 12 inspects non-zero operands in input vectors.

In step S404, for each two operands in the input vectors, in response to the operand in a former order of the input vector being inspected as zero by the swapper policy circuit 14, the swapper matrix circuit 16 swaps the non-zero operand in a latter order of the input vector with the operand in the former order of the input vector according to the MUX selection signal SW generated by the swapper policy circuit 14.

In some embodiments, for a first set of the operands and a second set of the operands in the input vectors, in response to the first set of the operands to be swapped in a first stage both being inspected as non-zero operands by the swapper policy circuit 14, the swapper matrix circuit 16 swaps the non-zero operand in a latter order in the first set with a zero operand in a latter order in the second set of the operands having two zero operands in a second stage before the first stage, and then swaps the non-zero operand being swapped to the second set with the operand in a former order in the second set.

In step S406, the adder tree 18 performs additions on the input vectors with the swapped operands to output a computation result.

In some embodiments, the adder tree 18 comprises a plurality of adders divided into a plurality of levels, in which each of a plurality of adders in a first level performs additions on N bits of two operands in the input vectors with the swapped operands, wherein N is a positive integer, and each of a plurality of adders in a M-th level of the plurality of levels performs additions on bits output by one or more adders in a (M-1)-th level, wherein M is a positive integer.

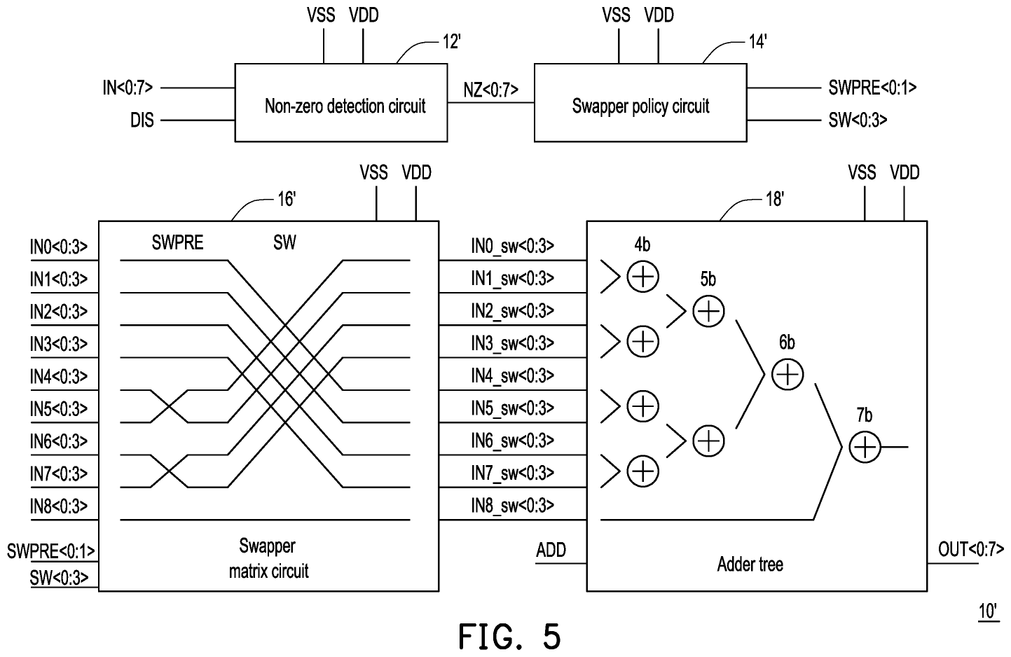

FIG. 5 is a circuit diagram of a computation apparatus in accordance with some embodiments of the present disclosure. Referring to FIG. 5, the present embodiment illustrates exemplified circuits implemented in the computation apparatus 10 in FIG. 1. The computation apparatus 10′ of the present embodiment includes a non-zero detection circuit 12′, a swapper policy circuit 14′, a swapper matrix circuit 16′, and an adder tree 18′.

The non-zero detection circuit 12′ is operated under a drain voltage VDD and a source voltage VSS, and is configured to receive input vectors IN<0:7> and a disable signal DIS, inspect non-zero operands in the input vectors IN<0:7>, and generate a non-zero indicative signal NZ<0:7> indicating the non-zero operands.

The swapper policy circuit 14′ is operated under a drain voltage VDD and a source voltage VSS, and is configured to receive the non-zero indicative signal NZ<0:7> and interpret the non-zero indicative signal NZ<0:7> to generate pre-selection signals SWPRE<0:1> for first stage swapping and selection signals SW<0:3> for second stage swapping.

The swapper matrix circuit 16′ is operated under a drain voltage VDD and a source voltage VSS, and is configured to receive the operands IN0<0:3> to IN8<0:3> of the input vectors IN<0:7>, the pre-selection signals SWPRE<0:1> and the selection signals SW<0:3>, so as to perform first stage swapping on the operands IN4<0:3> to IN7<0:3> according to the pre-selection signals SWPRE<0:1> and perform second stage swapping on the swapped input vectors according to the selection signals SW<0:3>, and output swapped operands IN0_sw<0:3> to IN8_sw<0:3>.

The adder tree 18′ is a four-level adder tree including four first-level adders 4b in a first level, two second-level adders 5b in a second level, one third-level adder 6b in a third level, and one fourth-level adder 7b in a fourth level, and configured to receive the swapped operands IN0_sw<0:3> to IN7_sw<0:3> output by the swapper matrix circuit 16′ and addition signals ADD. Each of the first-level adders 4b receives two of the swapped operands IN0_sw<0:3> to IN7_sw<0:3> and perform additions on the received operands to generate an addition result of the first level. Each of the second-level adders 5b receives two of the addition results of the first level output by the first-level adders 4b and performs additions on the received addition results to generate an addition result of the second level. The third-level adder 6b receives the addition results of the second level and performs additions on the received addition results to generate an addition result of the third level. The fourth-level adder 7b receives the addition result of the third level and the swapped operands IN8_sw<0:3> and performs additions on the received addition results and operands to generate the computation result OUT<0:7>.

Detailed circuit structures of the non-zero detection circuit 12′, the swapper policy circuit 14′, the swapper matrix circuit 16′, and the adder tree 18′ are described below, respectively.

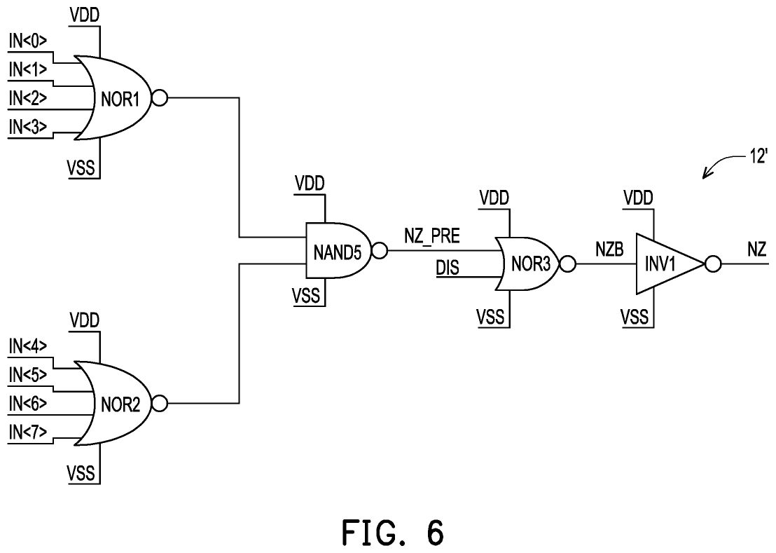

FIG. 6 is a circuit diagram of a non-zero detection circuit in accordance with some embodiments of the present disclosure. Referring to FIG. 6, the non-zero detection circuit 12′ includes two first exclusive OR gates NOR1 and NOR2, a NAND gate NAND 1, a second exclusive OR gate NOR3 and an inverter INV1.

Each of the first exclusive OR gates NOR1 and NOR2 is configured to receive four of the operands IN<0> to IN<7> in the input vectors IN<0:7> and generate a first output. The NAND gate NAND1 is coupled to the first exclusive OR gates NOR1 and NOR2 and configured to receive the first outputs and generate a second output NZ-PRE. The second exclusive OR gate NOR3 is coupled to the NAND gate NAND1 and configured to receive the second output NZ-PRE and the disable signal DIS, and generate a third output NZB according to the disable signal DIS. The inverter INV1 is coupled to the exclusive OR gate NOR3 and configured to invert the third output NZB to generate the non-zero indicative signal NZ.

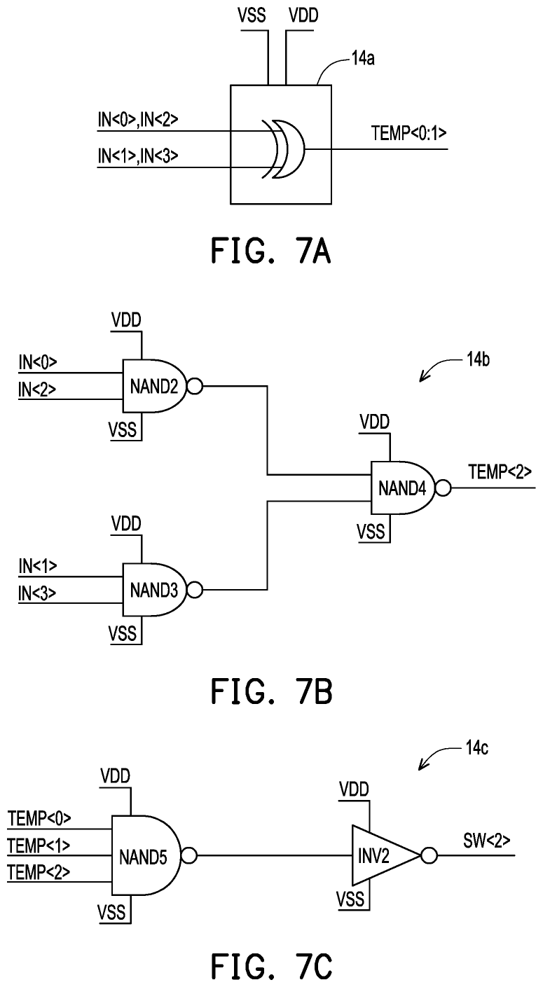

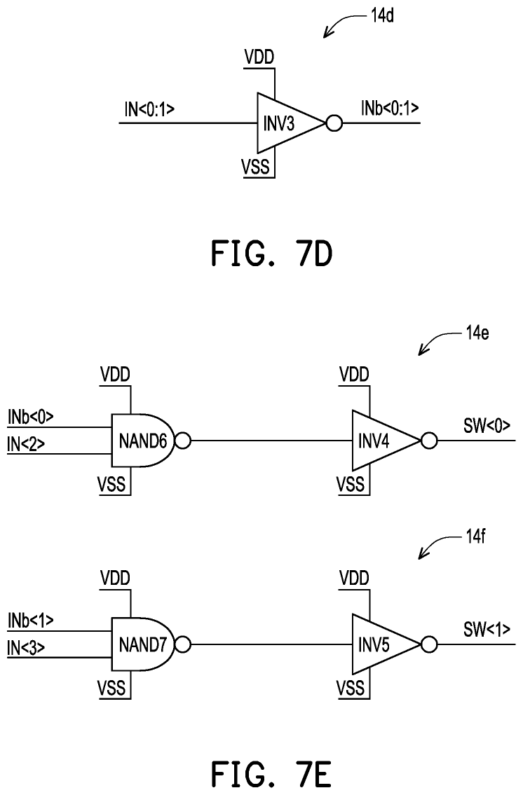

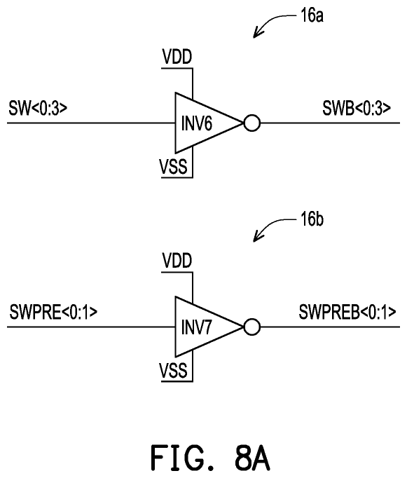

FIGS. 7A to 7E are circuit diagrams of a swapper policy circuit in accordance with some embodiments of the present disclosure. Referring to FIG. 5 and FIG. 7A to 7E, the swapper policy circuit 14′ includes sub-circuits 14a to 14f as shown in FIG. 7A to 7E, respectively.

Referring to FIG. 7A, the sub-circuit 14a is operated under a drain voltage VDD and a source voltage VSS, and includes two exclusive OR gates, respectively used to perform exclusive OR operation on the operands IN<0> and IN<1> and operands IN<2> and IN<3> to generate intermediate operands TEMP<0:1>.

Referring to FIG. 7B, the sub-circuit 14b is operated under a drain voltage VDD and a source voltage VSS, and includes two first NAND gates NAND2 and NAND3 and a second NAND gate NAND4. The first NAND gates NAND2 and NAND3 are configured to receive the operands IN<0> and IN<2> and operands IN<1> and IN<3>, respectively, so as to generate outputs. The second NAND gate NAND4 is configured to receive the outputs of the first NAND gates NAND2 and NAND3, so as to generate an intermediate operand TEMP<2>.

Referring to FIG. 7C, the sub-circuit 14c is operated under a drain voltage VDD and a source voltage VSS, and includes a NAND gate NAND5 and an inverter INV2. The NAND gate NAND5 is configured to receive the intermediate operands TEMP<0> to TEMP<2> from the sub-circuits 14a and 14b, and generate a selection signal SW<2>.

Referring to FIG. 7D, the sub-circuit 14d is operated under a drain voltage VDD and a source voltage VSS, and includes an inverter INV3. The inverter INV3 is configured to receive the operands IN<0:1> and generate inverted operands INb<0:1>.

Referring to FIG. 7E, the sub-circuit 14e is operated under a drain voltage VDD and a source voltage VSS, and includes a NAND gate NAND6 and an inverter INV4. The NAND gate NAND6 is configured to receive the inverted operand INb<0> and the operand IN<2>, and generates an output. The inverter INV4 is configured to receive the output from the NAND gate NAND6 and generate a selection signal SW<0>. The sub-circuit 14f is operated under a drain voltage VDD and a source voltage VSS, and includes a NAND gate NAND7 and an inverter INV5. The NAND gate NAND7 is configured to receive the inverted operand INb<1> and the operand IN<3>, and generates an output. The inverter INV5 is configured to receive the output from the NAND gate NAND7 and generate a selection signal SW<1>.

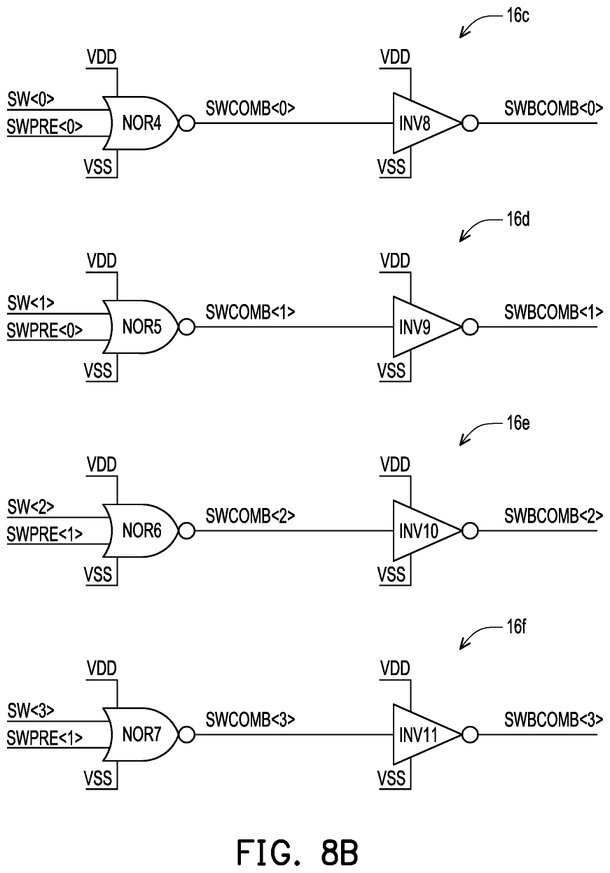

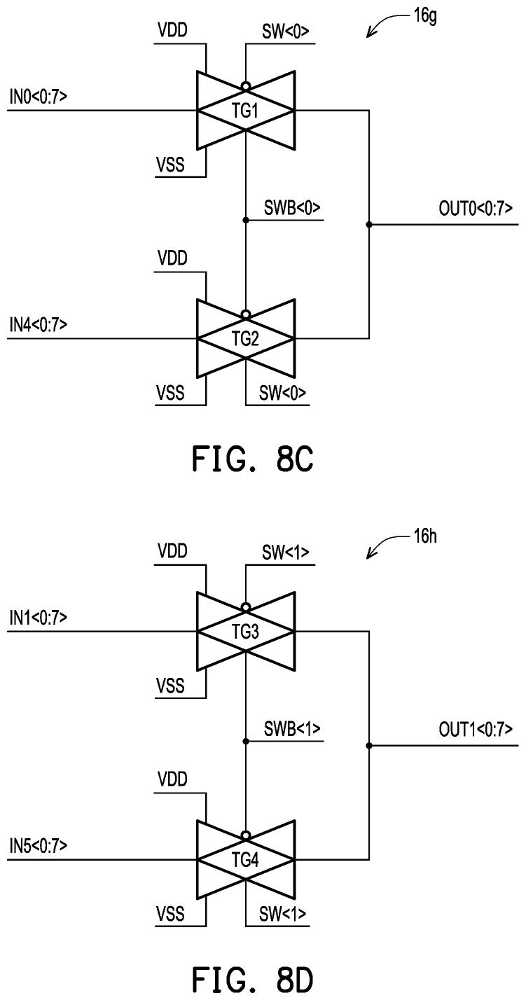

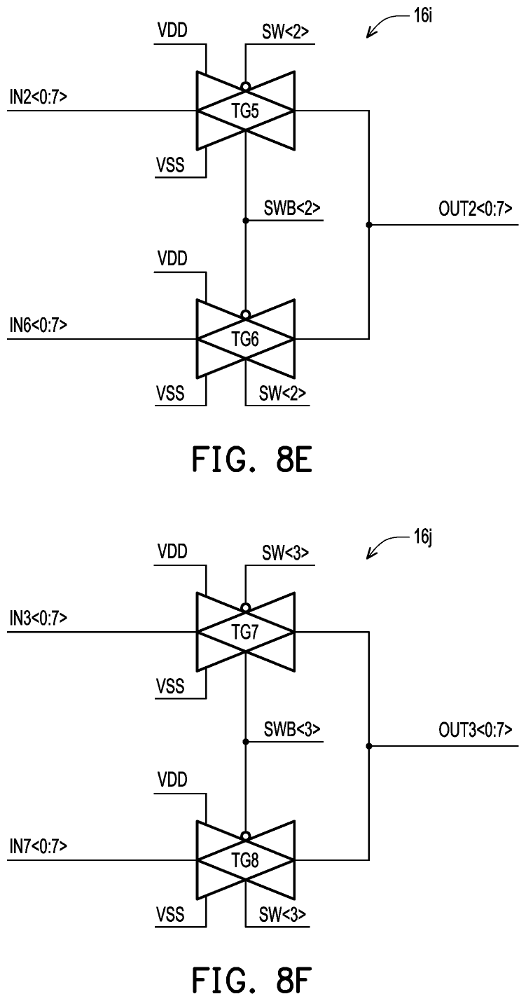

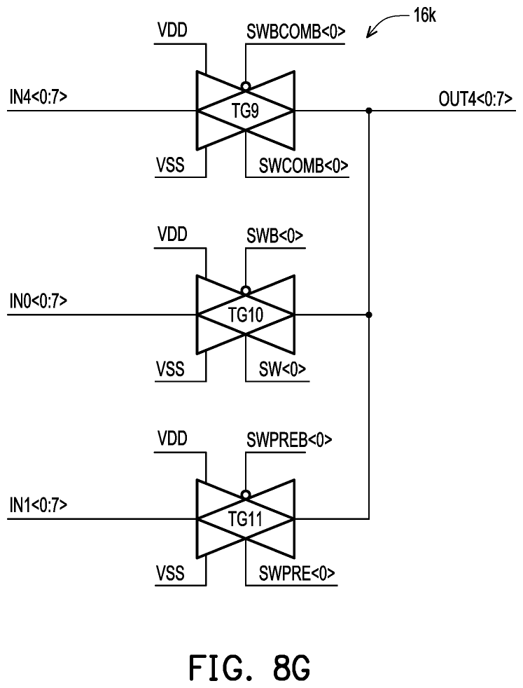

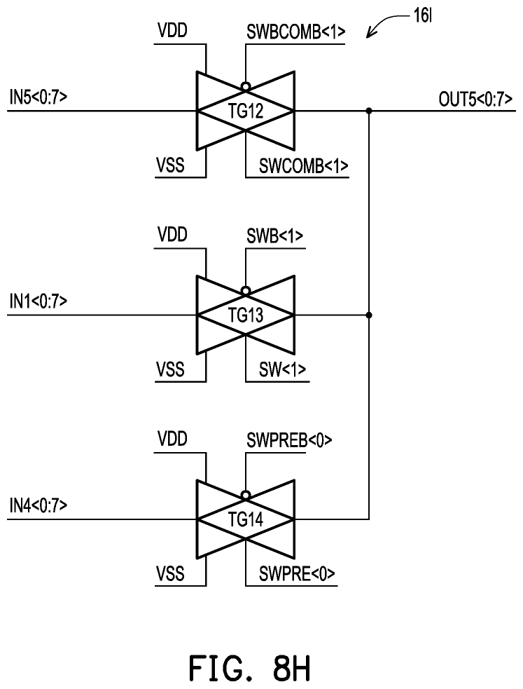

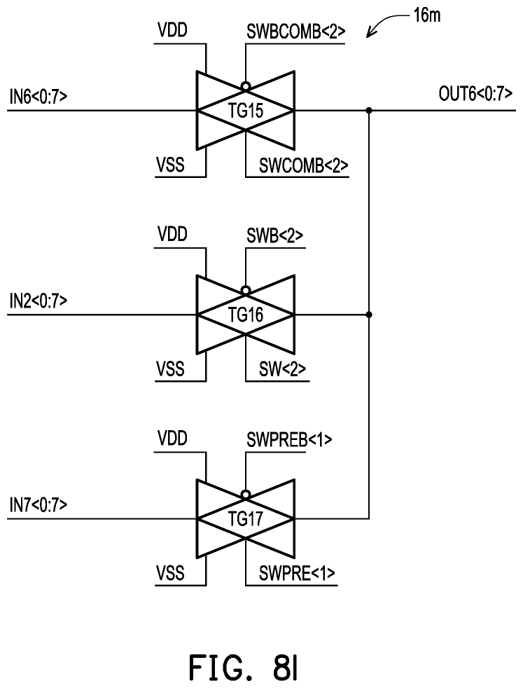

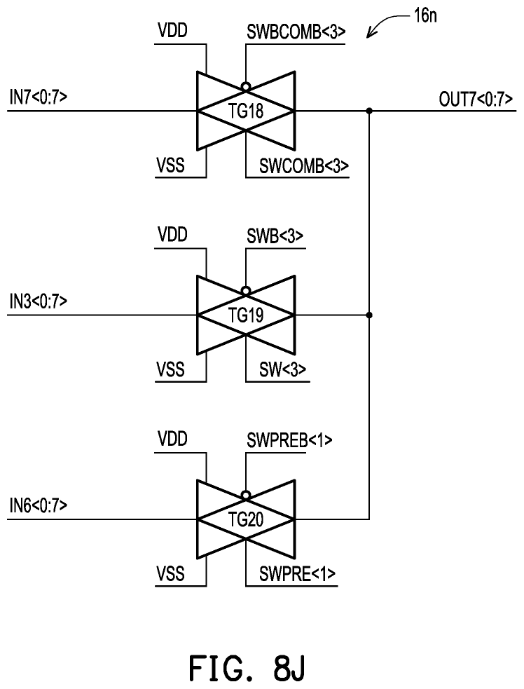

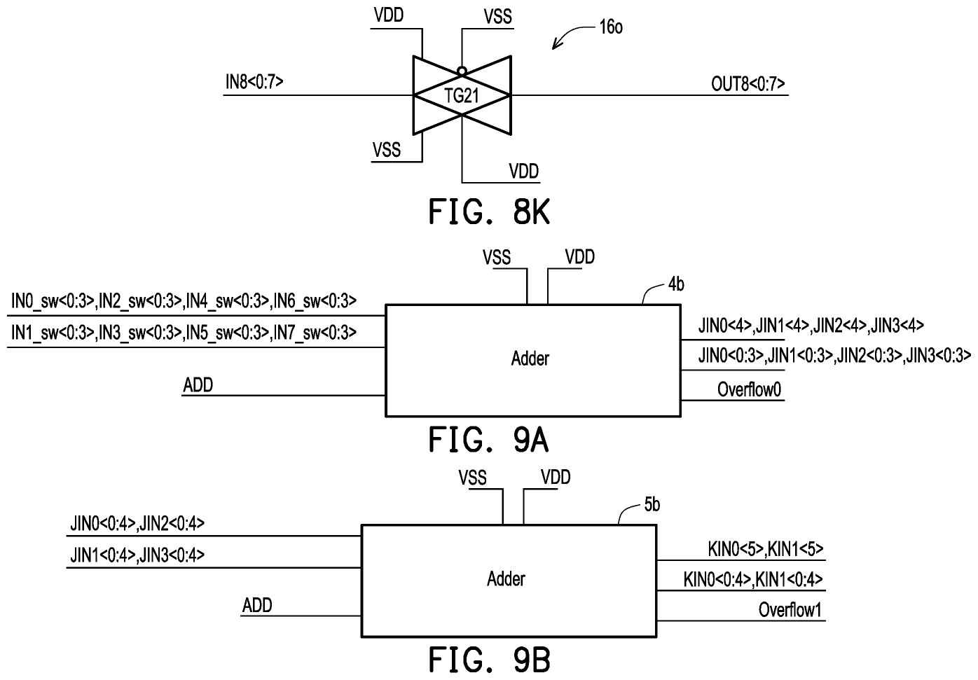

FIGS. 8A to 8K are circuit diagrams of a swapper matrix circuit in accordance with some embodiments of the present disclosure. Referring to FIG. 5 and FIG. 8A to 8K, the swapper matrix circuit 16′ includes sub-circuits 16a to 14o as shown in FIG. 8A to 8K, respectively.

Referring to FIG. 8A, the sub-circuit 16a is operated under a drain voltage VDD and a source voltage VSS, and includes an inverter INV6 that receives the selection signals SW<0:3> and generates inverted selection signals SWB<0:3>. The sub-circuit 16b is operated under a drain voltage VDD and a source voltage VSS, and includes an inverter INV7 that receives the pre-selection signals SWPRE<0:1> and generates inverted pre-selection signals SWPREB<0:1>.

Referring to FIG. 8B, the sub-circuit 16c is operated under a drain voltage VDD and a source voltage VSS, and includes an exclusive OR gate NOR4 that receives the selection signal SW<0> and the pre-selection signal SWPRE<0> and generates combined selection signal SWCOMB<0> and an inverter INV8 that receives the combined selection signal SWCOMB<0> and generated an inverted combined selection signal SWBCOMB<0>.

The sub-circuit 16d is operated under a drain voltage VDD and a source voltage VSS, and includes an exclusive OR gate NOR5 that receives the selection signal SW<1> and the pre-selection signal SWPRE<0> and generates combined selection signal SWCOMB<1> and an inverter INV9 that receives the combined selection signal SWCOMB<1> and generated an inverted combined selection signal SWBCOMB<1>.

The sub-circuit 16e is operated under a drain voltage VDD and a source voltage VSS, and includes an exclusive OR gate NOR6 that receives the selection signal SW<2> and the pre-selection signal SWPRE<1> and generates combined selection signal SWCOMB<2> and an inverter INV10 that receives the combined selection signal SWCOMB<2> and generated an inverted combined selection signal SWBCOMB<2>.

The sub-circuit 16f is operated under a drain voltage VDD and a source voltage VSS, and includes an exclusive OR gate NOR7 that receives the selection signal SW<3> and the pre-selection signal SWPRE<1> and generates combined selection signal SWCOMB<3> and an inverter INV11 that receives the combined selection signal SWCOMB<3> and generated an inverted combined selection signal SWBCOMB<3>.

Referring to FIG. 8C, the sub-circuit 16g is operated under a drain voltage VDD and a source voltage VSS, and includes two transmission gates TG1 and TG2. The transmission gate TG1 is configured to receive operands IN0<0:7> of the input vectors IN<0:7> and the transmission gate TG2 is configured to receive operands IN4<0:7> of the input vectors IN<0:7>. The transmission gates TG1 and TG2 are controlled by the selection signal SW<0> and the inverted selection signal SWB<0> to perform switching on the operands IN0<0:7> and IN4<0:7> and generate output operands OUT0<0:7>.

Referring to FIG. 8D, the sub-circuit 16h is operated under a drain voltage VDD and a source voltage VSS, and includes two transmission gates TG3 and TG4. The transmission gate TG3 is configured to receive operands IN1<0:7> of the input vectors IN<0:7> and the transmission gate TG4 is configured to receive operands IN5<0:7> of the input vectors IN<0:7>. The transmission gates TG3 and TG4 are controlled by the selection signal SW<1> and the inverted selection signal SWB<1> to perform switching on the operands IN1<0:7> and IN5<0:7> and generate output operands OUT1<0:7>.

Referring to FIG. 8E, the sub-circuit 16i is operated under a drain voltage VDD and a source voltage VSS, and includes two transmission gates TG5 and TG6. The transmission gate TG5 is configured to receive operands IN2<0:7> of the input vectors IN<0:7> and the transmission gate TG6 is configured to receive operands IN6<0:7> of the input vectors IN<0:7>. The transmission gates TG5 and TG6 are controlled by the selection signal SW<2> and the inverted selection signal SWB<2> to perform switching on the operands IN2<0:7> and IN6<0:7> and generate output operands OUT2<0:7>.

Referring to FIG. 8F, the sub-circuit 16j is operated under a drain voltage VDD and a source voltage VSS, and includes two transmission gates TG7 and TG8. The transmission gate TG7 is configured to receive operands IN3<0:7> of the input vectors IN<0:7> and the transmission gate TG8 is configured to receive operands IN7<0:7> of the input vectors IN<0:7>. The transmission gates TG7 and TG8 are controlled by the selection signal SW<3> and the inverted selection signal SWB<3> to perform switching on the operands IN3<0:7> and IN7<0:7> and generate output operands OUT3<0:7>.

Referring to FIG. 8G, the sub-circuit 16k is operated under a drain voltage VDD and a source voltage VSS, and includes three transmission gates TG9 to TG11. The transmission gate TG9 is configured to receive operands IN4<0:7> of the input vectors IN<0:7>, the transmission gate TG10 is configured to receive operands IN0<0:7> of the input vectors IN<0:7>, and the transmission gate TG11 is configured to receive operands IN1<0:7> of the input vectors IN<0:7>. The transmission gates TG9 is controlled by the combined selection signal SWCOMB<0> and the inverted combined selection signal SWBCOMB<0>, the transmission gates TG10 is controlled by the selection signal SW<0> and the inverted selection signal SWB<0> and the transmission gates TG11 is controlled by the pre-selection signal SWPRE<0> and the inverted pre-selection signal SWPREB<0>, so as to perform switching on the operands IN4<0:7>, IN0<0:7> and IN1<0:7> and generate output operands OUT4<0:7>.

Referring to FIG. 8H, the sub-circuit 161 is operated under a drain voltage VDD and a source voltage VSS, and includes three transmission gates TG12 to TG14. The transmission gate TG12 is configured to receive operands IN5<0:7> of the input vectors IN<0:7>, the transmission gate TG13 is configured to receive operands IN1<0:7> of the input vectors IN<0:7>, and the transmission gate TG14 is configured to receive operands IN4<0:7> of the input vectors IN<0:7>. The transmission gates TG12 is controlled by the combined selection signal SWCOMB<1> and the inverted combined selection signal SWBCOMB<1>, the transmission gates TG13 is controlled by the selection signal SW<1> and the inverted selection signal SWB<1> and the transmission gates TG14 is controlled by the pre-selection signal SWPRE<0> and the inverted pre-selection signal SWPREB<0>, so as to perform switching on the operands IN5<0:7>, IN1<0:7> and IN4<0:7> and generate output operands OUT5<0:7>.

Referring to FIG. 8I, the sub-circuit 16m is operated under a drain voltage VDD and a source voltage VSS, and includes three transmission gates TG15 to TG17. The transmission gate TG15 is configured to receive operands IN6<0:7> of the input vectors IN<0:7>, the transmission gate TG16 is configured to receive operands IN2<0:7> of the input vectors IN<0:7>, and the transmission gate TG17 is configured to receive operands IN7<0:7> of the input vectors IN<0:7>. The transmission gates TG15 is controlled by the combined selection signal SWCOMB<2> and the inverted combined selection signal SWBCOMB<2>, the transmission gates TG16 is controlled by the selection signal SW<2> and the inverted selection signal SWB<2> and the transmission gates TG17 is controlled by the pre-selection signal SWPRE<1> and the inverted pre-selection signal SWPREB<1>, so as to perform switching on the operands IN6<0:7>, IN2<0:7> and IN7<0:7> and generate output operands OUT6<0:7>.

Referring to FIG. 8J, the sub-circuit 16n is operated under a drain voltage VDD and a source voltage VSS, and includes three transmission gates TG18 to TG20. The transmission gate TG18 is configured to receive operands IN7<0:7> of the input vectors IN<0:7>, the transmission gate TG19 is configured to receive operands IN3<0:7> of the input vectors IN<0:7>, and the transmission gate TG20 is configured to receive operands IN6<0:7> of the input vectors IN<0:7>. The transmission gates TG18 is controlled by the combined selection signal SWCOMB<3> and the inverted combined selection signal SWBCOMB<3>, the transmission gates TG19 is controlled by the selection signal SW<3> and the inverted selection signal SWB<3> and the transmission gates TG20 is controlled by the pre-selection signal SWPRE<1> and the inverted pre-selection signal SWPREB<1>, so as to perform switching on the operands IN7<0:7>, IN3<0:7> and IN6<0:7> and generate output operands OUT7<0:7>.

Referring to FIG. 8K, the sub-circuit 16o is operated under a drain voltage VDD and a source voltage VSS, and includes a transmission gate TG21. The transmission gate TG21 is configured to receive operands IN8<0:7> of the input vectors IN<0:7> and is controlled by signals of the drain voltage VDD and the source voltage VSS to generate output operands OUT8<0:7>.

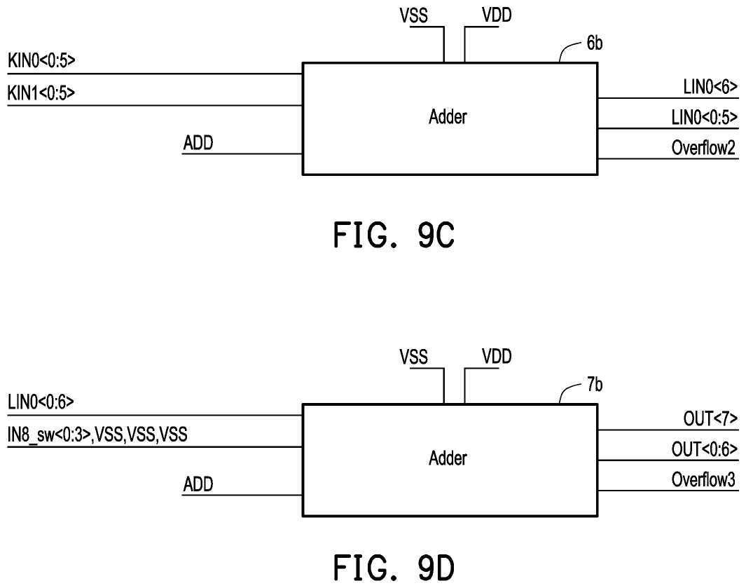

FIGS. 9A to 9D are circuit diagrams of adders in accordance with some embodiments of the present disclosure. Referring to FIG. 5 and FIG. 9A to 9D, FIGS. 9A to 9D respectively illustrates functions of the first-level adders 4b, the second-level adders 5b, the third-level adder 6b and the fourth-level adder 7b in the adder tree 18′ in FIG. 5.

In some embodiments, the adder tree 18′ comprises a plurality of adders divided into four levels, in which there are four adders 4b in a first level, two adders 5b in a second level, one adder 6b in a third level and one adder 7b in a fourth level. Each of the four adders 4b in the first level performs additions on four bits of the swapped operands of the input vectors. Each of the two adders 5b in the second level performs additions on five bits of the operands output by the adders 4b in the first level. The adder 6b in the third level performs additions on six bits of the operands output by the adders 5b in the second level. The adder 7b in the fourth level performs additions on seven bits of the operands output by the adders 6b in the third level.

Referring to FIG. 9A, the first-level adder 4b is operated under a drain voltage VDD and a source voltage VSS, and configured to receive the swapped operands IN0_sw<0:3> and IN1_sw<0:3> output by the swapper matrix circuit 16′ and an addition signal ADD, perform additions on the operands IN0_sw<0:3> and IN1_sw<0:3> according to the addition signal ADD, and generate addition results JIN0<0:3> and JIN0<4>. Similarly, the first-level adder 4b is configured to perform additions on the swapped operands IN2_sw<0:3> and IN3_sw<0:3> to generate addition results JIN1<0:3> and JIN1<4>, perform additions on the swapped operands IN4_sw<0:3> and IN5_sw<0:3> to generate addition results JIN2<0:3> and JIN2<4>, and perform additions on the swapped operands IN6_sw<0:3> and IN7_sw<0:3> to generate addition results JIN3<0:3> and JIN3<4>. The first-level adder 4b is configured to generate an overflow signal Overflow1 indicating the overflow generated during the additions.

Referring to FIG. 9B, the second-level adder 5b is operated under a drain voltage VDD and a source voltage VSS, and configured to receive the addition results JIN0<0:4> and JIN1<0:4> of the first-level adders 4b and an addition signal ADD, perform additions on the addition results JIN0<0:4> and JIN1<0:4> according to the addition signal ADD, and generate addition results KIN0<0:4> and KIN0<5>. Similarly, the second-level adder 5b is configured to perform additions on the addition results JIN2<0:4> and JIN3<0:4> according to the addition signal ADD, and generate addition results KIN1<0:4> and KIN1<5>. The second-level adder 5b is configured to generate an overflow signal Overflow2 indicating the overflow generated during the additions.

Referring to FIG. 9C, the third-level adder 6b is operated under a drain voltage VDD and a source voltage VSS, and configured to receive the addition results KIN0<0:5> and KIN1<0:5> of the second-level adders 5b and an addition signal ADD, perform additions on the addition results KIN0<0:5> and KIN1<0:5> according to the addition signal ADD, and generate addition results LIN0<0:5> and LIN0<6>. The third-level adder 6b is configured to generate an overflow signal Overflow3 indicating the overflow generated during the additions.

Referring to FIG. 9D, the fourth-level adder 7b is operated under a drain voltage VDD and a source voltage VSS, and configured to receive the addition results LIN0<0:6> of the third-level adders 6b, the operands IN8_sw<0:3> with three complementary operands provided by the source voltage VSS and an addition signal ADD, perform additions on the addition results LIN0<0:6> and IN8_sw<0:3> with complementary operands according to the addition signal ADD, and generate the computation results OUT<0:6> and OUT<7>.

Based on the above, in the computation apparatus and the computation method with input swapping, the non-zero operands in the input vectors are consolidated to one branch of the adder tree for additions such that a number of active adders used for addition is minimized. As a result, the computation power of an adder tree could be reduced significantly.

In accordance with some embodiments, a computation apparatus with input swapping is provided. The computation apparatus includes a non-zero detection circuit, a swapper policy circuit, a swapper matrix circuit, and an adder tree. The non-zero detection circuit is configured to receive input vectors, inspect non-zero operands in the input vectors and generate a non-zero indicative signal indicating the non-zero operands. The swapper policy circuit is configured to receive the non-zero indicative signal, interpret the non-zero indicative signal, and generate multiplexer (MUX) selection signals for swapping the non-zero operands according to a set of swapping policies. The swapper matrix circuit is configured to receive the input vectors and the MUX selection signal, and perform swapping on operands in the input vectors according to the MUX selection signal. The adder tree is configured to receive the input vectors with the swapped operands output by the swapper matrix circuit and perform additions on the received input vectors to output a computation result.

In some embodiments, the non-zero detection circuit includes a plurality of first exclusive OR gates, a NAND gate, and an inverter. Each of the first exclusive OR gates is configured to receive a portion of the operands in the input vectors and generate a first output. The NAND gate is coupled to the first exclusive OR gates and configured to receive the first outputs and generate a second output. The inverter is coupled to the NAND gate and configured to invert the second output to generate the non-zero indicative signal.

In some embodiments, the swapping policies includes, in response to the operand in a former order of the input vector being inspected as zero, swapping the non-zero operand in a latter order of the input vector with the operand in the former order of the input vector.

In some embodiments, the swapper policy circuit includes a first inverter, a NAND gate, and a second inverter. The first inverter is configured to invert the operand in the former order of the input vector. The NAND gate is coupled to the first inverter and configured to receive the inverted operand output by the first inverter and the operand in the latter order of the input vector and generate a first output. The second inverter is coupled to the NAND gate and configured to invert the first output to generate the MUX selection signals.

In some embodiments, the swapping policies includes, in response to a first set of the operands to be swapped in a first stage both being non-zero operands, swapping the non-zero operand in a latter order in the first set with a zero operand in a latter order in a second set of the operands having two zero operands in a second stage before the first stage, and swapping the non-zero operand being swapped to the second set with the operand in a former order in the second set.

In some embodiments, the swapper policy circuit includes two first NAND gates, a second NAND gate, a first exclusive OR gate, a second exclusive OR gate, and a third NAND gate. The first NAND gates are configured to respectively receive the operands of the first set and the operands of the second set and generate first outputs. The second NAND gate is coupled to the two first NAND gates and configured to receive the first outputs and generate a second output. The first exclusive OR gate is configured to receive a first operand of the first set and a first operand of the second set and generate a third output. The second exclusive OR gate is configured to receive a second operand of the first set and a second operand of the second set and generate a fourth output. The third NAND gate is coupled to the second NAND gate, the first exclusive OR gate and the second exclusive OR gate, and configured to receive the second output, the third output and the fourth output and generate a fifth output. The inverter is coupled to the third NAND gate and configured to invert the fifth output to generate the MUX selection signals.

In some embodiments, the swapper matrix circuit is a multi-stage transmission gate matrix including a plurality of transmission gates in each stage, and each of the plurality of transmission gates is configured to swap two of the operands in the input vectors according to the MUX selection signal.

In some embodiments, the adder tree includes a plurality of adders divided into a plurality of levels, in which each of a plurality of adders in a M-th level of the plurality of levels is configured to perform additions on bits output by one or more adders in a (M-1)-th level, wherein M is a positive integer, and each of a plurality of adders in a first level of the plurality of levels is configured to receive N bits of two operands in the input vectors output by the swapper matrix circuit, wherein N is a positive integer.

In accordance with some embodiments, a computation method with input swapping is provided. The computation method includes steps of: inspecting non-zero operands in input vectors by a non-zero detection circuit to generate a non-zero indicative signal indicating the non-zero operands; interpreting the non-zero indicative signal by a swapper policy circuit to generate MUX selection signals for swapping the non-zero operands according to a set of swapping policies; performing swapping on operands in the input vectors according to the MUX selection signal by a swapper matrix circuit; and performing additions on the input vectors with the swapped operands output by the swapper matrix circuit by an adder tree to output a computation result.

In some embodiments, inspecting non-zero operands in input vectors comprises performing an exclusive OR operation on portions of the operands in the input vectors to generate first outputs, performing an NAND operation on the first outputs to generate a second output, and inverting the second output and generating the non-zero indicative signal.

In some embodiments, the swapping policies comprise, in response to the operand in a former order of the input vector being inspected as zero, swapping the non-zero operand in a latter order of the input vector with the operand in the former order of the input vector.

In some embodiments, generating MUX selection signals for swapping the non-zero operands according to a set of swapping policies comprises inverting the operand in the former order of the input vector, performing an NAND operation on the inverted operand and the operand in the latter order of the input vector to generate a first output, and inverting the first output and generating the MUX selection signals.

In some embodiments, the swapping policies comprise, in response to a first set of the operands to be swapped in a first stage both being non-zero operands, swapping the non-zero operand in a latter order in the first set with a zero operand in a latter order in a second set of the operands having two zero operands in a second stage before the first stage, and swapping the non-zero operand being swapped to the second set with the operand in a former order in the second set.

In some embodiments, generating MUX selection signals for swapping the non-zero operands according to a set of swapping policies comprises performing an NAND operation on the operands of the first set and the operands of the second set, respectively, to generate first outputs, performing the NAND operation on the first outputs to generate a second output, performing an exclusive OR operation on a first operand of the first set and a first operand of the second set to generate a third output, performing the exclusive OR operation on a second operand of the first set and a second operand of the second set to generate a fourth output, performing the NAND operation on the second output, the third output and the fourth output to generate a fifth output; and inverting the fifth output and generating the MUX selection signals.

In some embodiments, performing swapping on operands in the input vectors according to the MUX selection signal comprises swapping two of the operands in the input vectors by each of a plurality of transmission gates in the swapper matrix circuit according to the MUX selection signal.

In some embodiments, the adder tree comprises a plurality of adders divided into a plurality of levels, and performing additions on the input vectors with the swapped operands output by the swapper matrix circuit by the adder tree to output the computation result comprises performing, by each of a plurality of adders in a first level of the plurality of levels, additions on N bits of two operands in the input vectors output by the swapper matrix circuit, wherein N is a positive integer, and performing, by each of a plurality of adders in a M-th level of the plurality of levels, additions on bits output by one or more adders in a (M-1)-th level, wherein M is a positive integer.

In accordance with some embodiments, a computation method with input swapping is provided. The computation method includes steps of: inspecting non-zero operands in input vectors; for each two operands in the input vectors, in response to the operand in a former order of the input vector being inspected as zero, swapping the non-zero operand in a latter order of the input vector with the operand in the former order of the input vector; and performing additions on the input vectors with the swapped operands by an adder tree to output a computation result.

In some embodiments, the computation method further comprising: for a first set of the operands and a second set of the operands in the input vectors, in response to the first set of the operands to be swapped in a first stage both being non-zero operands, swapping the non-zero operand in a latter order in the first set with a zero operand in a latter order in the second set of the operands having two zero operands in a second stage before the first stage, and swapping the non-zero operand being swapped to the second set with the operand in a former order in the second set.

In some embodiments, the adder tree comprises a plurality of adders divided into a plurality of levels, and performing additions on the input vectors with the swapped operands by the adder tree to output the computation result comprises performing, by each of a plurality of adders in a first level of the plurality of levels, additions on N bits of two operands in the input vectors with the swapped operands, wherein N is a positive integer, and performing, by each of a plurality of adders in a M-th level of the plurality of levels, additions on bits output by one or more adders in a (M-1)-th level, wherein M is a positive integer.

In some embodiments, the adder tree is a ripple carry adder constituted by multiple full-adders, in which each full adder takes a carry-in as input and produces a carry-out as output, and the carry-out produced by a full adder serves as the carry-in for adjacent most significant full adder. For example, a four-bit ripple carry adder includes four full adders for adding two 4-bit binary numbers, a five-bit ripple carry adder includes five full adders for adding two 5-bit binary numbers, and so on.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A computation apparatus with input swapping, comprising:
a non-zero detection circuit, configured to receive input vectors, inspect non-zero operands in the input vectors and generate a non-zero indicative signal indicating the non-zero operands;
a swapper policy circuit, configured to receive the non-zero indicative signal, interpret the non-zero indicative signal, and generate multiplexer (MUX) selection signals for swapping the non-zero operands according to a set of swapping policies;
a swapper matrix circuit, configured to receive the input vectors and the MUX selection signal, and perform swapping on operands in the input vectors according to the MUX selection signal; and
an adder tree, configured to receive the input vectors with the swapped operands output by the swapper matrix circuit and perform additions on the received input vectors to output a computation result.

2. The computation apparatus according to claim 1, wherein the non-zero detection circuit comprises:
a plurality of first exclusive OR gates, each of the first exclusive OR gates is configured to receive a portion of the operands in the input vectors and generate a first output;
a NAND gate, coupled to the first exclusive OR gates and configured to receive the first outputs and generate a second output; and
an inverter, coupled to the NAND gate and configured to invert the second output to generate the non-zero indicative signal.

3. The computation apparatus according to claim 1, wherein the swapping policies comprise:
in response to the operand in a former order of the input vector being inspected as zero, swapping the non-zero operand in a latter order of the input vector with the operand in the former order of the input vector.

4. The computation apparatus according to claim 3, wherein the swapper policy circuit comprises:
a first inverter, configured to invert the operand in the former order of the input vector;
a NAND gate, coupled to the first inverter and configured to receive the inverted operand output by the first inverter and the operand in the latter order of the input vector and generate a first output; and
a second inverter, coupled to the NAND gate and configured to invert the first output to generate the MUX selection signals.

5. The computation apparatus according to claim 1, wherein the swapping policies comprise:
in response to a first set of the operands to be swapped in a first stage both being non-zero operands, swapping the non-zero operand in a latter order in the first set with a zero operand in a latter order in a second set of the operands having two zero operands in a second stage before the first stage, and swapping the non-zero operand being swapped to the second set with the operand in a former order in the second set.

6. The computation apparatus according to claim 5, wherein the swapper policy circuit comprises:
two first NAND gates, configured to respectively receive the operands of the first set and the operands of the second set and generate first outputs;
a second NAND gate, coupled to the two first NAND gates and configured to receive the first outputs and generate a second output;
a first exclusive OR gate, configured to receive a first operand of the first set and a first operand of the second set and generate a third output;
a second exclusive OR gate, configured to receive a second operand of the first set and a second operand of the second set and generate a fourth output;
a third NAND gate, coupled to the second NAND gate, the first exclusive OR gate and the second exclusive OR gate, and configured to receive the second output, the third output and the fourth output and generate a fifth output; and
an inverter, coupled to the third NAND gate and configured to invert the fifth output to generate the MUX selection signals.

7. The computation apparatus according to claim 1, wherein the swapper matrix circuit is a multi-stage transmission gate matrix comprising a plurality of transmission gates in each stage, and each of the plurality of transmission gates is configured to swap two of the operands in the input vectors according to the MUX selection signal.

8. The computation apparatus according to claim 1, wherein
the adder tree comprises a plurality of adders divided into a plurality of levels,
each of a plurality of adders in a M-th level of the plurality of levels is configured to perform additions on bits output by one or more adders in a (M-1)-th level, wherein M is a positive integer, and
each of a plurality of adders in a first level of the plurality of levels is configured to receive N bits of two operands in the input vectors output by the swapper matrix circuit, wherein N is a positive integer.

9. The computation apparatus according to claim 8, wherein each of the plurality of adders is a ripple carry adder comprising a plurality of full adders connected in series.

10. A computation method with input swapping, comprising:
inspecting non-zero operands in input vectors by a non-zero detection circuit to generate a non-zero indicative signal indicating the non-zero operands;
interpreting the non-zero indicative signal by a swapper policy circuit to generate MUX selection signals for swapping the non-zero operands according to a set of swapping policies;
performing swapping on operands in the input vectors according to the MUX selection signal by a swapper matrix circuit; and
performing additions on the input vectors with the swapped operands output by the swapper matrix circuit by an adder tree to output a computation result.

11. The computation method according to claim 10, wherein inspecting non-zero operands in input vectors comprises:
performing an exclusive OR operation on portions of the operands in the input vectors to generate first outputs;
performing an NAND operation on the first outputs to generate a second output; and
inverting the second output and generating the non-zero indicative signal.

12. The computation method according to claim 10, wherein the swapping policies comprise:
in response to the operand in a former order of the input vector being inspected as zero, swapping the non-zero operand in a latter order of the input vector with the operand in the former order of the input vector.

13. The computation method according to claim 12, wherein generating MUX selection signals for swapping the non-zero operands according to a set of swapping policies comprises:
inverting the operand in the former order of the input vector;
performing an NAND operation on the inverted operand and the operand in the latter order of the input vector to generate a first output; and
inverting the first output and generating the MUX selection signals.

14. The computation method according to claim 10, wherein the swapping policies comprise:
in response to a first set of the operands to be swapped in a first stage both being non-zero operands, swapping the non-zero operand in a latter order in the first set with a zero operand in a latter order in a second set of the operands having two zero operands in a second stage before the first stage, and swapping the non-zero operand being swapped to the second set with the operand in a former order in the second set.

15. The computation method according to claim 14, wherein generating MUX selection signals for swapping the non-zero operands according to a set of swapping policies comprises:
performing an NAND operation on the operands of the first set and the operands of the second set, respectively, to generate first outputs;
performing the NAND operation on the first outputs to generate a second output;
performing an exclusive OR operation on a first operand of the first set and a first operand of the second set to generate a third output;
performing the exclusive OR operation on a second operand of the first set and a second operand of the second set to generate a fourth output;
performing the NAND operation on the second output, the third output and the fourth output to generate a fifth output; and
inverting the fifth output and generating the MUX selection signals.

16. The computation method according to claim 10, wherein performing swapping on operands in the input vectors according to the MUX selection signal comprises:
swapping two of the operands in the input vectors by each of a plurality of transmission gates in the swapper matrix circuit according to the MUX selection signal.

17. The computation method according to claim 10, wherein
the adder tree comprises a plurality of adders divided into a plurality of levels, and
performing additions on the input vectors with the swapped operands output by the swapper matrix circuit by the adder tree to output the computation result comprises:
performing, by each of a plurality of adders in a first level of the plurality of levels, additions on N bits of two operands in the input vectors output by the swapper matrix circuit, wherein N is a positive integer; and
performing, by each of a plurality of adders in a M-th level of the plurality of levels, additions on bits output by one or more adders in a (M-1)-th level, wherein M is a positive integer.

18. A computation method with input swapping, comprising:
inspecting non-zero operands in input vectors;
for each two operands in the input vectors, in response to the operand in a former order of the input vector being inspected as zero, swapping the non-zero operand in a latter order of the input vector with the operand in the former order of the input vector; and
performing additions on the input vectors with the swapped operands by an adder tree to output a computation result.

19. The computation method according to claim 18, further comprising:
for a first set of the operands and a second set of the operands in the input vectors, in response to the first set of the operands to be swapped in a first stage both being non-zero operands, swapping the non-zero operand in a latter order in the first set with a zero operand in a latter order in the second set of the operands having two zero operands in a second stage before the first stage, and swapping the non-zero operand being swapped to the second set with the operand in a former order in the second set.

20. The computation method according to claim 18, wherein
the adder tree comprises a plurality of adders divided into a plurality of levels, and
performing additions on the input vectors with the swapped operands by the adder tree to output the computation result comprises:
performing, by each of a plurality of adders in a first level of the plurality of levels, additions on N bits of two operands in the input vectors with the swapped operands, wherein N is a positive integer; and
performing, by each of a plurality of adders in a M-th level of the plurality of levels, additions on bits output by one or more adders in a (M-1)-th level, wherein M is a positive integer.
